(19) United States
(12) Patent Application Publication
(10) Pub. No.: US 2010/0314635 A1
(43) Pub. Date: Dec. 16, 2010

(54) CHIP ARRANGEMENT, CONNECTION ARRANGEMENT, LED AND METHOD FOR PRODUCING A CHIP ARRANGEMENT

(75) Inventors: Herbert Brunner, Sinzing (DE); Steffen Koehler, Penang (MY); Raimund Schwarz, Regensburg (DE); Stefan Grotsch, Lengfeld - Bad Abbach (DE)

Correspondence Address: IP GROUP OF DLA PIPER LLP (US), ONE LIBERTY PLACE, 1650 MARKET ST, SUITE 4900, PHILADELPHIA, PA, 19103, US

(73) Assignee: OSRAM OPTO SEMICONDUCTORS GMBH, Regensburg (DE)

(21) Appl. No.: 12/742,470

(22) PCT Filed: Nov. 21, 2008
(86) PCT No.: PCT/DE2008/001931

§ 371 Date: Jul. 6, 2010

(30) Foreign Application Priority Data
Nov. 28, 2007 (DE) 10 2007 057 242.7
Apr. 30, 2008 (DE) 10 2008 021 618.6

(51) Int. Cl. H01L 33/52; H01L 33/62

(52) U.S. Cl. 257/88; 257/99; 438/122; 257/E21.504; 257/E33.061; 257/E33.058

(57) ABSTRACT

A chip arrangement for an optoelectronic component includes at least one semiconductor chip which emits electromagnetic radiation, and a connection arrangement which includes planes that are electrically insulated from one another, at least one plane having a cavity and at least one plane being a heat dissipating plane, wherein at least two electrically insulated conductors are arranged in at least the two planes, the semiconductor chip is arranged within the cavity and has at least two connection locations, and each of the connection locations is electrically conductively connected to a respective one of the conductors.

### RELATED APPLICATIONS

This is a §371 of International Application No. PCT/DE2008/001931, with an international filing date of Nov. 21, 2008 (WO 2009/067996 A2, published Jun. 4, 2009), which is based on German Patent Application Nos. 10 2007 057 242.7, filed Nov. 28, 2007, and 10 2008 021 618.6, filed Apr. 30, 2008, the subject matter of which is incorporated by reference.

### TECHNICAL FIELD

This disclosure relates to a chip arrangement for an optoelectronic component comprising at least one semiconductor chip which emits electromagnetic radiation and comprising a connection arrangement.

### BACKGROUND

So-called “semiconductor components” are preferably used nowadays as a light source. A luminescence diode (LED), also referred to as light-emitting diode, is thereby a very cost-effective and effective light source. The starting point for the production of LED chips is a monocrystalline base material. Silicon and germanium may be mentioned by way of example. Silicon has IV-valent silicon atoms, IV-valent elements having four valence electrons for atomic bonds.

By doping the base material, donor and/or acceptor atoms are introduced into the crystal lattice of the base material. As a result, properties, for example, the conductivity of the base material are altered in a targeted manner. In the case of n-type doping, for example, where n represents the freely mobile negative charge that is introduced, V-valent elements, so-called “donors,” are introduced into the silicon lattice and replace IV-valent silicon atoms therefor. A V-valent element has five valence electrons available for atomic bonds such that, upon incorporation into the silicon crystal, one valence electron of the donor is available in freely mobile fashion. The electron can perform work when a voltage is applied. At the location of the donor atom, a stationary positive bond arises, which is opposed by a negative charge of the freely mobile electron. By way of example, phosphorus, arsenic or antimony is used for the n-type doping of a base material.

In contrast, in the case of p-type doping, where p represents the freely mobile positive gap (hole), III-valent elements, so-called “acceptors,” are introduced into the silicon lattice and replace the IV-valent silicon atom. III-valent elements analogously have three valence electrons for atomic bonds. When a voltage is applied, the hole behaves like a freely mobile positive charge carrier and can perform work analogously to the negatively charged electron. At the location of the acceptor atom, a stationary negative charge arises, which is opposed by a positive charge of the freely mobile hole. Boron, indium, aluminum or allium, for example, is used to dope a semiconductor component in p-type fashion.

The III-V semiconductor gallium arsenide could likewise be doped with the IV-valent elements carbon, silicon or with gold.

For the emission of electromagnetic radiation, LED chips require a so-called “pn structure,” that is to say a p-doped material is connected to an n-doped material. As a result of the application of an electrical voltage that is higher than the threshold voltage of the structure, light having a specific wavelength is emitted by the pn structure. In this case, the wavelength, the intensity of the light and the magnitude of the electrical voltage to be applied are dependent on the type of doping and the construction of the respective pn structure.

The construction of an LED chip (=light-emitting semiconductor chip) is not necessarily always identical. The p-doped layer can be arranged on a top side of an LED chip, on the one hand, or on an underside of the LED chip, on the other hand. These types of LED chips are referred to by experts as p-up n-down LED chips. In this case it is unimportant whether there is a p-type connection location or an n-type connection location on the top side. The corresponding other connection location of an LED chip is situated on the corresponding opposite side of the LED chip. In this case, a substrate between the connection locations should preferably be configured such that it is electrically non-insulating, that is to say electrically conductive.

In another LED construction, both the n-type connection location and the p-type connection location are arranged on a top side of the LED chip. In such a case, the substrate should ideally be configured such that it is electrically insulating.

The expression “differently constructed LED chips or semiconductor chips” is equated hereinafter with the differently arranged n-type and/or p-type connection locations.

To increase the emitted light power of an LED, to mix different wavelengths and/or optimize the emitted light cone to different requirements, it is customary to arrange a plurality of light-emitting semiconductor chips (=LED chips) in a common housing.

To obtain diverse interconnection variants for power light sources, it is necessary, for example, to accommodate a plurality of differently constructed semiconductor chips in a common arrangement or in a common housing. Such an arrangement is also referred to as a chip arrangement. To introduce differently constructed semiconductor chips within a chip arrangement, complicated interconnection concepts have been realized hitherto within the arrangement. Although these interconnection concepts prevent possible short-circuiting of the LED chips and enable individual driving of the individual LED, they can only be realized in a very complicated manner, as a result of which the costs for production are very high. In addition, in the case of these chip arrangements it is difficult to produce optimum heat dissipation for the respective LED chip.

It could therefore be helpful to arrange a plurality of differently constructed semiconductor chips within a chip arrangement without having to design cost-intensive interconnection concepts and, furthermore, provide an optimum heat linking for each individual semiconductor chip.

### SUMMARY

We provide a chip arrangement for an optoelectronic component, including at least one semiconductor chip which emits electromagnetic radiation, and a connection arrangement including planes that are electrically insulated from one another, at least one plane having a cavity, and at least one plane being a heat dissipating plane, wherein at least two electrically insulated conductors are arranged in at least the two planes, the semiconductor chip is arranged within the cavity and has at least two connection locations, and each of the connection locations is electrically conductively connected to a respective one of the conductors.

We also provide a connection arrangement for an optoelectronic component including a plurality of planes electrically insulated from one another, wherein a first plane is a connection plane, a second plane is a heat dissipating plane, and the individual planes are encapsulated by plastic; and at least two electrically insulated conductors arranged in the at least two planes.

We further provide an LED including a housing, a covering, electrical connections and the connection arrangement, wherein the electrical connections are electrically conductively connected to the conductors, and at least one semiconductor chip is introduced in the cavity.

We still further provide a method for producing a chip arrangement including producing a first leadframe as a connection leadframe, producing a second leadframe as a heat dissipating leadframe, encapsulating the leadframes by injection molding, forming a cavity within at least one of the leadframes, introducing semiconductor chips within the cavity, electrically connecting the semiconductor chips to the leadframes, and potting the semiconductor chips within the cavity.

### BRIEF DESCRIPTION OF THE DRAWINGS

Our structures and methods are explained below on the basis of examples with reference to the drawings, wherein the figures of identical or identically acting constituent parts are in each case identified by the same reference symbols. The elements illustrated should not be regarded as true to scale. Rather, individual elements may be illustrated with an exaggerated size or with exaggerated simplification to provide a better understanding.

FIG. 1 shows an example of a chip arrangement.

FIG. 2 shows a development of the chip arrangement illustrated in FIG. 1.

FIG. 3A shows a plan view of the chip arrangement illustrated in FIG. 2 with a possible interconnection of the individual semiconductor chips.

FIG. 3B shows a plan view of the chip arrangement illustrated in FIG. 2 with an alternative interconnection.

FIG. 4 shows a development of the chip arrangement illustrated in FIG. 2.

FIG. 5 shows an LED with a chip arrangement.

FIG. 6 shows a development of the LED illustrated in FIG. 5.

FIGS. 7A to 7D show three-dimensional examples of the LED and chip arrangement illustrated in FIGS. 2 to 6.

FIGS. 8A to 8C show possible constructions of LED chips.

### DETAILED DESCRIPTION

We provide a chip arrangement for an optoelectronic component, comprising at least one semiconductor chip which emits electromagnetic radiation, and comprising a connection arrangement, wherein the connection arrangement has planes that are electrically insulated from one another, at least two electrically insulated conductors are arranged in at least two planes, at least one plane has a cavity, the semiconductor chip is arranged within the cavity and has at least two connection locations, each of the connection locations is electrically conductively connected to a respective one of the conductors and at least one of the planes is a heat dissipating plane.

In addition, in one configuration of the chip arrangement, a second semiconductor chip, which is not necessarily constructed like the first semiconductor chip, is introduced within the cavity. The second semiconductor chip likewise has at least two connection locations and each of the connection locations is electrically conductively connected to a respective conductor. For this purpose, one of the two planes has at least one third conductor electrically insulated from the other conductors. If two differently constructed LED chips are arranged within the chip arrangement, then this chip arrangement makes it possible for the two LED chips to be interconnected in series. For this purpose, the second plane should advantageously be embodied as electrically conductive. In another circuit concept, the second connection location of the at least second semiconductor chip is connected to a further, electrically insulated conductor of the first plane, as a result of which separate driving of the LED chips can be realized. In this interconnection, the heat dissipating plane can be embodied such that it is electrically non-conductive. Consequently, it is possible in a simple manner for an interconnection concept to be realized and for the differently constructed semiconductor chips to be driven individually or together or to be connected to one another in any desired manner.

In a further configuration, the heat dissipating layer is divided and the parts of the heat dissipating plane are spatially separated from one another. This measure makes it possible for the heat to be optimally dissipated individually for each semiconductor chip. As a result, it is also possible, depending on the respective differently constructed semiconductor chip, to provide a differently sized part of the heat dissipating plane to be ideally adapted to the conditions of the LED chip.

If differently constructed semiconductor chips are introduced into the arrangement, a series circuit comprising the individual chips is possible without additional insulation or additional electrical connection. If identically constructed semiconductor chips are introduced into the arrangement, then the second plane is embodied as a common electrically insulated conductor.

In an alternative configuration, the individual semiconductor chips can be interconnected in series and/or in parallel. The connection arrangement makes it possible, in a simple manner, to design an interconnection that is as simple as possible by means of the at least two planes. As a result, different wavelengths, for example an RGB arrangement, can be driven individually, flexibly and optimally. Furthermore, the light intensity of the chip arrangement can be increased as a result.

In a further configuration, the chip arrangement is provided with an optical element. This optical element makes it possible to deflect, reflect or concentrate the emitted electromagnetic radiation. Optimum illumination is thereby achieved.

In a further advantageous configuration, the connection arrangement is equipped with a third plane, the holding plane, which is embodied as a holding plane for the optical element. By extending the connection arrangement with this third plane, it is possible to create a cost-effective arrangement.

As a result of encapsulating the individual planes with a plastic, the individual layers can be produced in an electrically insulated fashion and furthermore in a cost-effective fashion.

In a further configuration, the chip arrangement has the electrical connections which are configured in the form of plug contacts, soldering pins or insulation displacement connections, which are electrically conductively connected to the individual conductors. It is thereby possible to produce an electrical driving with respect to the chip arrangement by means of ISO- or IEC-standardized plug contacts, for example.

In a further advantageous configuration, the semiconductor chips are realized with an insulating platinum substrate. Preferably, both connection locations of the LED chip are arranged on a first top side of the LED chip. In addition, it is possible for the heat dissipating plane to be configured as electrically insulating, that is to say not electrically conductive.

In a further advantageous configuration, the heat dissipating plane is a heat sink and can be thermally dissipated directly with an electrically conductive cooling body. In this case, the heat dissipating plane should preferably be configured such that it is electrically conductive. First, sufficient removal of heat is thereby achieved. The heat that arises in the interior of the chip arrangement as a result of the semiconductor chips is thus optimally dissipated. Second, an electrically conductive connection is realized in a simple manner.

We provide a connection arrangement for an optoelectronic component and also an LED comprising a housing, a covering, electrical connections and a multichip arrangement.

The connection arrangement for an optoelectronic component is preferably constructed from a plurality of planes electrically insulated from one another, wherein at least two electrically insulated conductors are arranged in at least two planes, the individual planes are encapsulated by means of plastic, a first plane of the connection arrangement is a connection plane, and a second plane of the connection arrangement is a heat dissipating plane.

Preferably, the connection arrangement has a third plane, which is embodied as a holding plane for an optical element.

The LED comprising a housing preferably has a covering, electrical connections and a connection arrangement, wherein the electrical connections are electrically conductively connected to the conductors, and at least one second semiconductor chip is introduced in the cavity.

Preferably, the heat dissipating plane is divided and the parts are spatially separated from one another in such a way that heat can be optimally dissipated to the housing individually for each semiconductor chip.

Particularly preferably, the electrical connections are plug contacts, soldering pins and/or insulation displacement connections.

Preferably, the semiconductor chips have an electrically insulating platinum substrate.

Preferably, the housing can be thermally coupled directly to an electrically conductive cooling body.

In addition, a method for producing a chip arrangement is also provided, comprising the following method steps:
producing a first leadframe and embodying the first leadframe as a connection leadframe,
producing a second leadframe and embodying the second leadframe as a heat dissipating leadframe,
encapsulating the leadframes by injection molding methods,
forming a cavity within at least one leadframe,
positioning semiconductor chips within the cavity,
electrically connecting the semiconductor chips to the leadframes, and
potting the semiconductor chips within the cavity.

“Leadframe” is understood here to mean an introduced intermediate material which is inserted into the respective plane. This intermediate material is preferably a stamped metal sheet or some other stamped electrically conductive material. The adaptations required in the respective plane are performed by the stamping. In the first plane, this concerns the formation of the insulated conductors, which are all still mechanically connected by a surrounding frame during production. In the heat dissipating plane, division of the material is preferably performed for the purpose of better heat dissipation. Here, too, the parts of the heat dissipating plane are still mechanically connected by a frame surrounding the area during production.

In one preferred configuration, a third frame, the holding leadframe, is likewise inserted, wherein the holding leadframe holds an optical element or the covering of the chip arrangement.

In one preferred configuration, the semiconductor chips have a non-insulating substrate and are interconnected in series.

In one preferred configuration, the heat dissipating layer is directly connected to an electrically conductive cooling body and dissipates the heat generated by the semiconductor chips.

If the leadframes have been introduced into the arrangement and encapsulated by plastic in a further method step, first, an insulation between the individual leadframes is produced. The frames still mechanically connecting everything are separated in a further method step, as a result of which only the stamped regions remain and ideally no mechanical or electrical connection prevails between the individual stampings. Starting from this method step, the leadframes correspond to the connection arrangement.

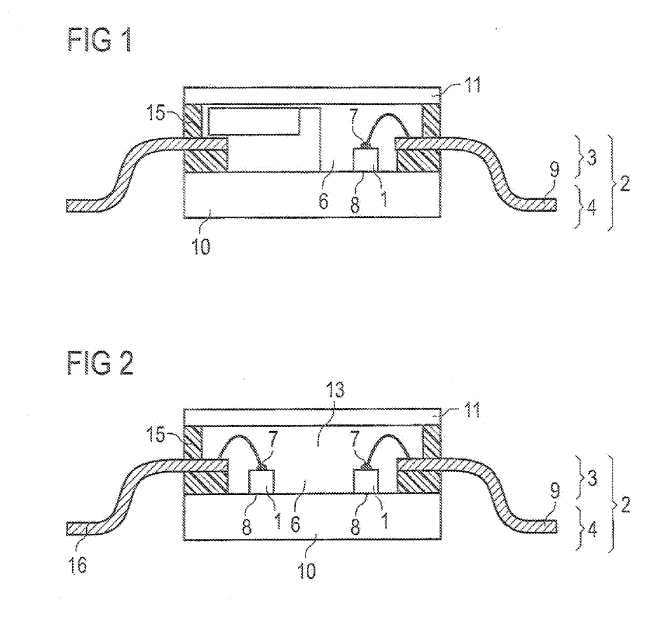

Turning now to the drawings, FIG. 1 shows an example of a chip arrangement. A connection arrangement 2 having a first plane 3 and a second plane 4 is illustrated. A semiconductor chip 1 is introduced within a cavity 6 of the connection arrangement 2. Furthermore, a potting compound 13 can be provided within the cavity 6. The individual planes 3 and 4 of the connection arrangement 2 are electrically insulated from one another. For this purpose, the individual layers 3 and 4 are encapsulated with a plastic material 15. A covering 11 terminates the cavity 6 and protects the semiconductor chips from external influences. In addition, the first plane 3 has a first conductor 9. The semiconductor chip 1 is electrically conductively connected to the first conductor 9 by a first connection location 7. The connection can preferably be realized by means of bonding methods. The second plane 4 has a second conductor 10. The second connection location 8 of the semiconductor chip 1 is electrically conductively connected to the second conductor 10. The two connection locations 7 and 8 are often referred to in the art as anode and cathode, it remaining open which connection location 7 or 8 is specifically anode or cathode. A function of the semiconductor chip, that is to say the light emission of the LED, should be striven for herein in the case of every circuit concept, as a result of which the second plane 4 should be embodied such that it is electrically conductive.

Optimum heat dissipation for the semiconductor chip 1 and an ideal interconnection concept are brought about by this arrangement.

In a production method, the conductors 9, 10 are situated in a first and a second leadframe, respectively, wherein the frame that mechanically connects the conductors during production is removed after the encapsulation of the arrangement. These leadframes correspond to the respective plane 3 or 4.

FIG. 2 shows a development of the chip arrangement illustrated in FIG. 1. Only the differences between FIGS. 1 and 2 are discussed below. At least one second semiconductor chip 1 is additionally introduced in the cavity 6. The first connection location 7 of the chip is connected, ideally by a bonding connection, to a third connection contact 16 of the first plane 3. The second connection location 8 of the second semiconductor chip 1 is likewise electrically conductively connected to the second conductor 10 of the second plane 4.

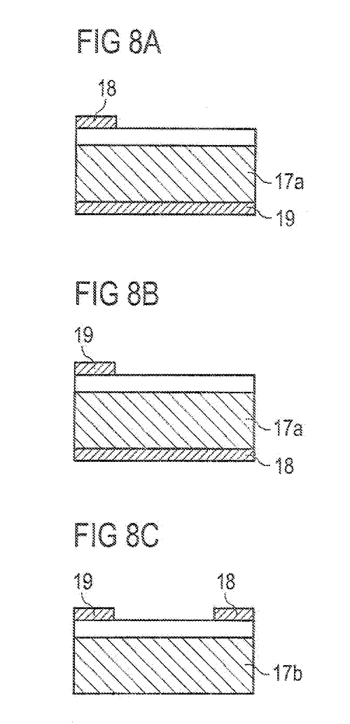

The at least two semiconductor chips 1 can be, for example, differently constructed semiconductor chips 1. For clarification, reference should be made to FIG. 8. In a first case, a series circuit comprising the semiconductor chips 1 is achieved by the second plane 4, which is ideally configured in electrically conductive fashion. By contrast, if at least two identically constructed semiconductor chips are introduced into the chip arrangement, the second plane 4 is the common reference point. Either the anode or the cathode of the semiconductor chip 1 can be connected to the common reference point. Operation of the individual semiconductor chips 1 is then achieved by individual voltage driving via the first plane 3.

By means of this chip arrangement, specifically by insertion of the separate interconnection plane 3, a more flexible interconnection of differently constructed semiconductor chips 1 can be realized without having to employ complicated insulation layers or circuit concepts.

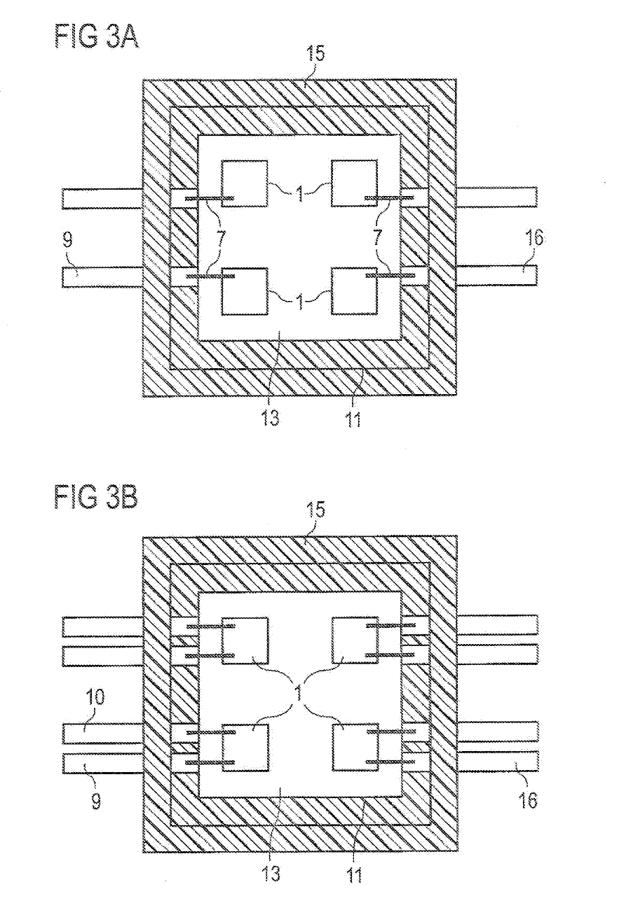

FIGS. 3A and 3B in each case show a plan view of a chip arrangement from FIG. 2. In FIG. 3A, four semiconductor chips 1 are introduced in a chip arrangement. The second connection locations 8 of the semiconductor chip 1 are all connected by the second plane 4, which is configured in electrically conductive fashion. In addition to the first conductor 9 and third conductor 16, further electrical conductors are provided in the first plane for the third and fourth semiconductor chip 1. The illustration additionally shows that the covering 11 is fitted into the plastic material 15.

In a second case (not illustrated), the respective semiconductor chips 1 are constructed differently. Here, too, reference should again be made to FIG. 8 for clarification. By means of the second plane 4, the chips 1 are interconnected in series with one another. As a result, it is then merely necessary to lead a first conductor 9 and a third conductor 16 toward the outside in an electrically conductive manner by the first plane 3 and to control them by a voltage to be applied. In this case, the voltage to be applied has to be higher than the threshold voltage of all the series-connected semiconductor chips 1 to ensure light emission of the semiconductor chips 1.

In contrast to FIG. 3A, in FIG. 3B each connection location 7 and 8 of the respective semiconductor chip 1 is led toward the outside with an electrically insulated conductor in the first plane 3. Consequently, the second plane 4 is only provided as a heat dissipating plane. In this case, it need not necessarily be configured in electrically conductive fashion. Preferably, the second plane 4 is embodied such that is it electrically insulating. Since both connection locations 7, 8 are arranged on a top side of the semiconductor chips, an insulating substrate can be provided within the semiconductor chips 1. Consequently, each semiconductor chip 1 is driven separately.

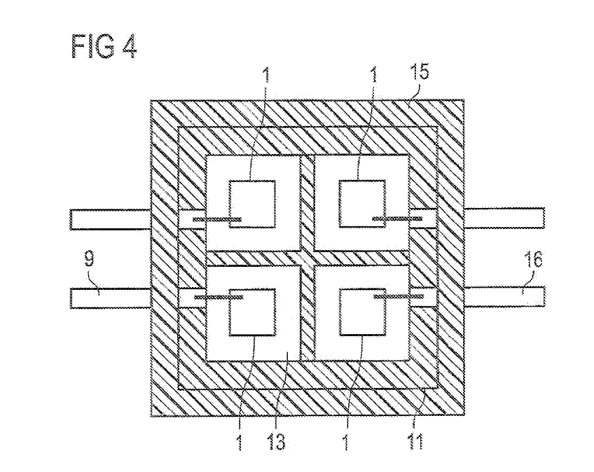

FIG. 4 shows a development of the chip arrangement illustrated in FIG. 3A. In contrast to FIG. 3A, the second plane is spatially divided in FIG. 4.

Optimum heat dissipation is obtained as a result of the division of the second plane 4. The division of the second layer 4 need not necessarily be symmetrical. Rather, it should be adapted to the heat dissipating requirements of the respective differently constructed semiconductor chips 1. In this case, the driving and the introduction of the individual semiconductor chips 1 are the same as the scenarios described in FIG. 3A. The electrical conductivity of the entire layer 4 is provided by mounting the chip arrangement on an electrically conductive cooling body or by SMT mounting. Division of the heat dissipating plane for the example illustrated in FIG. 3B is not illustrated. Since each chip can be individually driven herein, the heat dissipating plane and also the cooling body can be configured in electrically insulating fashion.

FIG. 5 shows an LED with one of the chip arrangements described above. In contrast to FIG. 2, a lens as an optical element 14 is provided instead of the covering 11. The optical element 14 makes it possible in a simplified manner to concentrate, scatter or deflect the light beams.

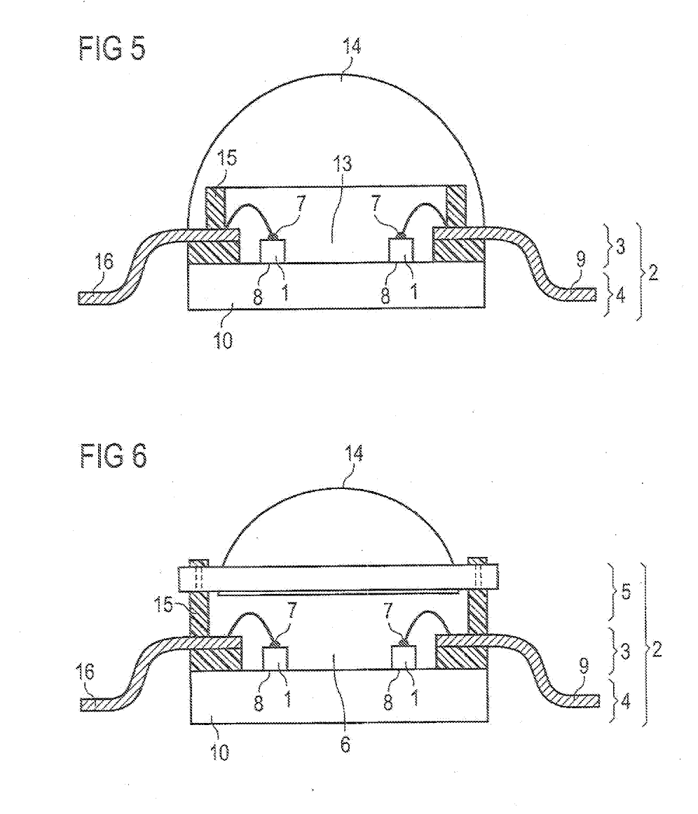

FIG. 6 shows a development of the LED illustrated in FIG. 5. Here, the connection arrangement 2 has three planes, wherein the third plane 5 serves as a holding plane for the optical element 14. The lens is preferably composed of silicone or some other thermoplastic. By means of injection molding methods, epoxides are preferably introduced between the individual layers 3, 4 and 5 of the connection arrangement 2 and thereby produce the electrical insulation of the individual planes.

The third plane 5 can likewise be produced by a leadframe in a production method. In principle, therefore, three areas should be stamped out to produce such a chip arrangement. The areas have the properties required for the respective plane with regard to electrical and thermal conductivity. With respect to the properties, other materials can be employed per leadframe. The leadframes are ideally encapsulated by means of plastic after their production and arrangement. An injection molding method should preferably be employed for this purpose. As a result, first, electrical insulation of the individual leadframes is achieved and, second, interconnection of differently constructed semiconductor chips 1 is made possible in a simplified manner by means of this multilayer leadframe production. After encapsulation has been effected, frames around the individual conductors 9, 10, 16 or the heat dissipating layer 4 and the holding layer 5 are removed.

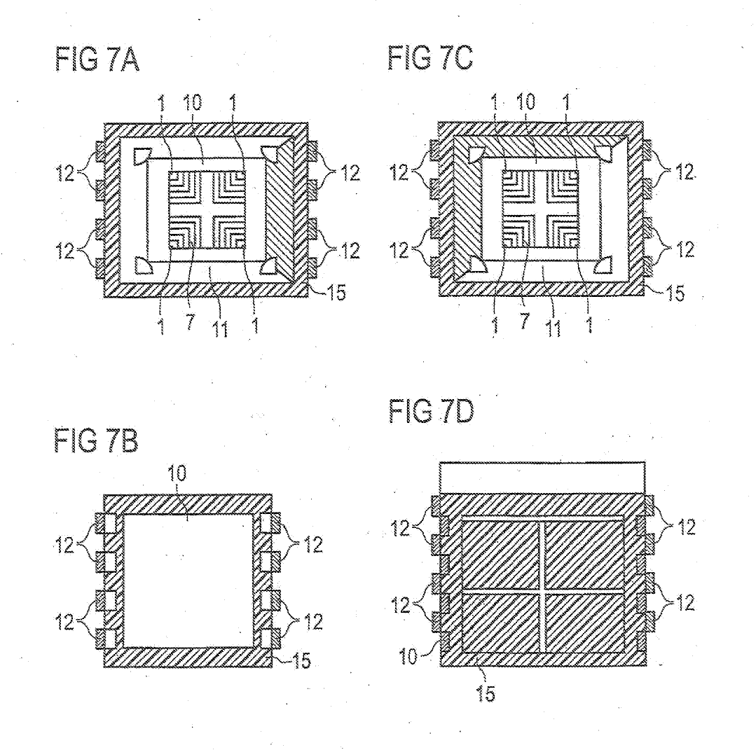

FIGS. 7A to 7D show different three-dimensional LEDs with chip arrangements. The electrical connections 12 serve in this case as SMT contact-connections. In another case, the electrical connections 12 can be embodied as plug contacts, soldering pins and/or insulation displacement connections. These electrical connections 12 are preferably IEC- or DIN-standardized. In FIGS. 7A and 7C, the semiconductor chips 1 additionally have current conducting rails that counteract a poor current conductivity of the respective doped material. The current conducting rails can be configured such that they are star-shaped, round, square or adapted to the respective conditions.

FIG. 8 illustrates the semiconductor chips 1 initially constructed fundamentally differently. In FIG. 8a, a non-insulating substrate 17a is provided with an n-type connection location 19 on an underside. A p-type connection location 18 is provided on the side opposite the underside. In contrast thereto, the two connection locations 18, 19 are interchanged in FIG. 8b. In FIG. 8c, an insulating substrate 17b is formed with connection locations 18, 19 provided on a top side.

Generally, an injection molding method serves to introduce epoxides between the individual layers of the connection arrangement, as a result of which the electrical insulation of the individual layers is achieved. By means of the connection arrangement, the interconnection plane 3 is separated from the heat conducting plane 4, as a result of which the interconnection and connection plane is equipped with more functionality.

In addition, current conducting tracks can also be arranged on the semiconductor chip 1 to counteract the poor conductivity of the doped base material.

1-15. (canceled)

16. A chip arrangement for an optoelectronic component, comprising:
at least one semiconductor chip which emits electromagnetic radiation, and
a connection arrangement comprising planes that are electrically insulated from one another, at least one plane having a cavity, and at least one plane being a heat dissipating plane,
wherein at least two electrically insulated conductors are arranged in at least the two planes, the seminconductor chip is arranged within the cavity and has at least two connection locations, and each of the connection locations is electrically conductively connected to a respective one of the conductors.

17. The chip arrangement as claimed in claim 16, wherein:
at least one second semiconductor chip is provided within the cavity and has at least two connection locations,
at least one third, electrically insulated conductor is arranged in one of the two planes, and
each of the connection locations of the second semiconductor chip is electrically conductively connected to a respective one of the conductors.

18. The chip arrangement as claimed in claim 16, wherein:
at least one second semiconductor chip is provided within the cavity and has at least two connection locations,
at least two further electrically insulated conductors are arranged in the at least two planes, and
each of the connection locations of the second semiconductor chip is electrically conductively connected to a respective one of the further conductors.

19. The chip arrangement as claimed in claim 17, wherein the heat dissipating plane is divided and the parts are spatially separated from one another such that heat can be optimally dissipated individually for each semiconductor chip.

20. The chip arrangement as claimed in claim 18, wherein the heat dissipating plane is divided and the parts are spatially separated from one another such that heat can be optimally dissipated individually for each semiconductor chip.

21. The chip arrangement as claimed in claim 17, wherein the semiconductor chips can be interconnected in series and/or in parallel within the chip arrangement.

22. The chip arrangement as claimed in claim 18, wherein the semiconductor chips can be interconnected in series and/or in parallel within the chip arrangement.

23. The chip arrangement as claimed in claim 18, wherein at least one of the planes is configured in electrically insulated fashion.

24. The chip arrangement as claimed in claim 16, wherein the chip arrangement has an optical element.

25. The chip arrangement as claimed in claim 16, wherein the connection arrangement has a third plane and the third plane is a holding plane for the optical element.

26. The chip arrangement as claimed in claim 16, wherein the conductors are electrically conductively connected to electrical connections in the form of plug contacts, soldering pins and/or insulation displacement connections.

27. The chip arrangement as claimed in claim 16, wherein the semiconductor chips have an electrically insulating platinum substrate.

28. The chip arrangement as claimed in claim 16, wherein the heat dissipating plane is a heat sink and can be thermally coupled directly to an electrically conductive cooling body.

29. A connection arrangement for an optoelectronic component comprising:
a plurality of planes electrically insulated from one another, wherein a first plane is a connection plane, a second plane is a heat dissipating plane, and the individual planes are encapsulated by plastic; and
at least two electrically insulated conductors arranged in the at least two planes.

30. An LED comprising a housing, a covering, electrical connections and a connection arrangement as claimed in claim 29, wherein the electrical connections are electrically conductively connected to the conductors, and at least one semiconductor chip is introduced in the cavity.

31. A method for producing a chip arrangement comprising:
producing a first leadframe as a connection leadframe,
producing a second leadframe as a heat dissipating leadframe,
encapsulating the leadframes by injection molding,
forming a cavity within at least one of the leadframes,
introducing semiconductor chips within the cavity,
electrically connecting the semiconductor chips to the leadframe, and
potting the semiconductor chips within the cavity.

32. The method as claimed in claim 31, wherein the heat conducting leadframe is spatially divided and heat is thereby optimally dissipated for each semiconductor chip.
